(19) United States
(12) Patent Application Publication
(10) Pub. No.: US 2014/0057394 A1
(43) Pub. Date: Feb. 27, 2014

(54) METHOD FOR MAKING A DOUBLE-SIDED FANOUT SEMICONDUCTOR PACKAGE WITH EMBEDDED SURFACE MOUNT DEVICES, AND PRODUCT MADE

(71) Applicants: Anandan Ramasamy, Singapore (SG); Yonggang Jin, Singapore (SG); Yun Liu, Singapore (SG); Eric Saugier, Villard Bonnot (FR); Romain Coffy, Saint Martin Le Vinoux (FR); How Yuan Hwang, Sitiawan Perak (MY)

(72) Inventors: Anandan Ramasamy, Singapore (SG); Yonggang Jin, Singapore (SG); Yun Liu, Singapore (SG); Eric Saugier, Villard Bonnot (FR); Romain Coffy, Saint Martin Le Vinoux (FR); How Yuan Hwang, Sitiawan Perak (MY)

(73) Assignees: STMicroelectronics Pte Ltd., Singapore (SG); STMicroelectronics (Grenoble 2) SAS, Grenoble (FR)

(21) Appl. No.: 13/594,498

(22) Filed: Aug. 24, 2012

(51) Int. Cl. H01L 21/60; H01L 21/56

(52) U.S. Cl. 438/113; 438/612; 257/E21.507; 257/E21.502

(57) ABSTRACT

A manufacturing process includes forming a reconstituted wafer, including embedding semiconductor dice in a molding compound layer and forming through-wafer vias in the layer. A fan-out redistribution layer is formed on a front side of the wafer, with electrical traces interconnecting the dice, through-wafer vias, and contact pads positioned on the redistribution layer. Solder balls are positioned on the contact pads and a molding compound layer is formed on the redistribution layer, reinforcing the solder balls. A second fan-out redistribution layer is formed on a back side of the wafer, with electrical traces interconnecting back ends of the through-wafer vias and contact pads positioned on a back face of the second redistribution layer. Flip-chips and/or surface-mounted devices are coupled to the contact pads of the second redistribution layer and encapsulated in an underfill layer formed on the back face of the second redistribution layer.

### BACKGROUND

1. Technical Field

Embodiments of the present disclosure are related to manufacturing processes of semiconductor packages, and in particular, to wafer level packaging of devices that incorporates a plurality of components or packages within the footprint of a single package, such as, e.g., system-in-package (SiP) devices and package-on-package (PoP) devices.

2. Description of the Related Art

For manufacturers of semiconductor devices, there is a continuing market pressure to increase the density and reduce the size of the devices, so that packages can be made smaller and more devices can be fit into ever smaller spaces, and so that products that incorporate the devices can be made more compact. One response to this pressure has been the development of chip scale and wafer level packaging. Chip scale packages have a footprint that is very close to the actual area of the semiconductor die. They are generally direct surface mountable, using, e.g., flip chip configurations. Wafer-level packages are packages in which some portion of the “back-end” processing is performed on all of the chips in a wafer, before the wafer is singulated.

Another development is the reconstituted wafer, also referred to as a reconfigured wafer, in which a semiconductor wafer is separated into individual dice, which are reformed into a reconstituted wafer. The dice are spaced some greater distance apart than on the original wafer, and embedded in a layer of molding compound, after which additional processing steps are performed on the reconstituted wafer. One benefit is that this provides increased area for each die for back end processes, such as the formation of contacts at a scale or pitch that is compatible with circuit board limitations, without sacrificing valuable real estate on the original wafer. Some packages of this type are known as fan-out wafer level packages, because the contact positions of the original die are “fanned out” to a larger foot print.

“System-in-package” (SiP) is a type of semiconductor package in which multiple devices are enclosed within a single package. Typically, the multiple devices include one or more dice mounted onto a chip carrier substrate and wirebonded to a wiring circuit of the substrate. The entire assembly is encapsulated as a single unit. The dice may be positioned side-by-side on the substrate, or stacked on each other. Other components, such as passive components, antennae, etc., can also be included.

“Package-on-Package” (POP) is a configuration in which one semiconductor package is stacked on top of another package, with, typically, solder connections between contact pads on the bottom surface of the upper package and the top surface of the lower package. In some cases, through-mold vias are provided, i.e., electrically conductive paths extending vertically through the lower package, enabling direct connection of the upper package with an underlying circuit board.

### BRIEF SUMMARY

According to an embodiment, a manufacturing process is provided, which includes forming a reconstituted wafer, including embedding semiconductor dice in a molding compound layer and forming through-wafer vias in the molding compound layer. A fan-out redistribution layer is formed on a front side of the wafer, with electrical traces interconnecting circuit contacts of the dice, through-wafer vias, and contact pads of the redistribution layer. Solder balls are coupled to the contact pads and a molding compound layer is formed on the redistribution layer, which reinforces the solder balls and reduces joint failure resulting from thermal mismatch.

A second fan-out redistribution layer is formed on a back side of the wafer, with electrical traces interconnecting back ends of the through-wafer vias and contact pads of the second redistribution layer. Flip-chips and/or surface-mounted devices are coupled to the contact pads of the second redistribution layer and encapsulated in an molded underfill layer formed on the back face of the second redistribution layer.

According to an embodiment, the last step of the process is singulation, meaning that the entire packaging process is performed at the wafer level.

According to an embodiment, the outermost dielectric layer of the fan-out redistribution layer formed on the front side of the wafer is made to completely cover the contact pads of the first redistribution layer. Later, before the solder balls are coupled to the contact pads, openings are made in the outermost dielectric layer over each of the plurality of contact pads by laser ablation.

According to an embodiment, a chemical coating is deposited over the contact pads of the second redistribution layer. Solder paste is used to couple surface-mounted devices to the contact pads of the second redistribution layer. During a process to reflow the solder paste, flux in the solder paste dissolves the chemical coating between the solder and the respective contact pad.

According to an embodiment, a semiconductor package is provided, manufactured according to one of the processes disclosed below.

### BRIEF DESCRIPTION OF THE SEVERAL VIEWS OF THE DRAWINGS

FIGS. 1-8 are schematic side views of a reconstituted wafer, according to an embodiment, at respective stages of the manufacture of a plurality of semiconductor packages, of which FIGS. 4-8 show an enlarged view of a smaller portion of the reconstituted wafer, defined in FIG. 3 by arrows 4-4.

FIGS. 9 and 10 are schematic side views of a reconstituted wafer, according to another embodiment, at respective stages of manufacture.

FIGS. 11-14 are schematic side views of a reconstituted wafer at respective stages of a manufacturing process according to another embodiment.

### DETAILED DESCRIPTION

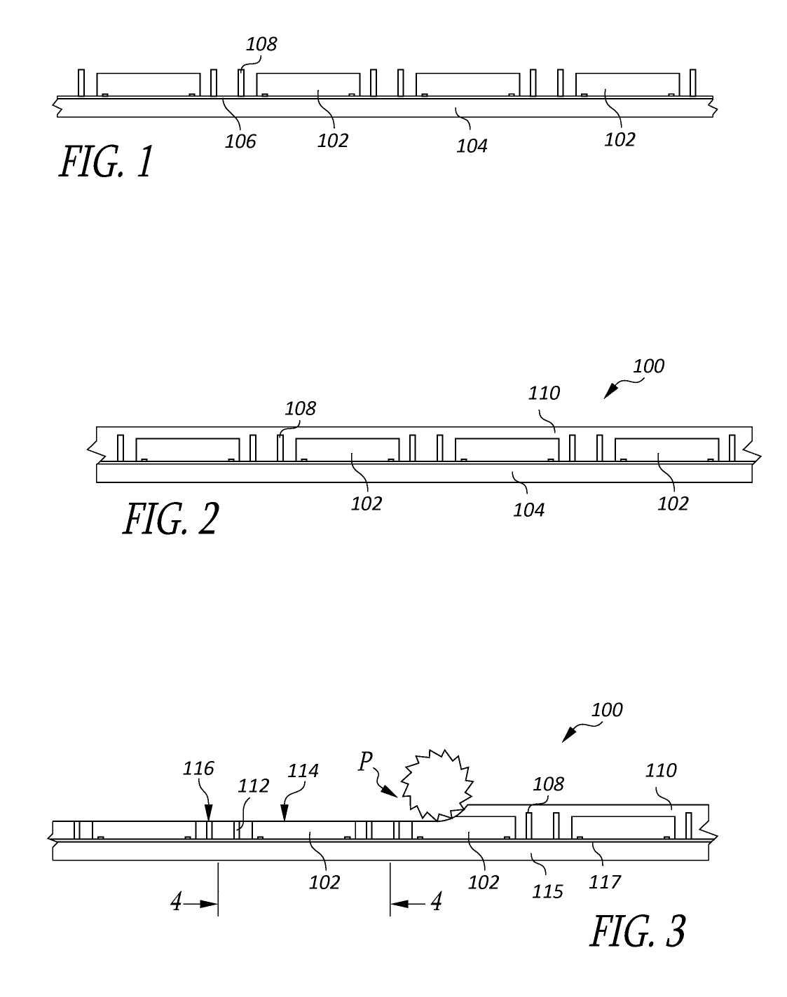

FIGS. 1-8 are schematic side views of a reconstituted wafer 100 at respective stages of the manufacture of a plurality of semiconductor packages, according to an embodiment. As shown in FIGS. 1 and 2, in a pick-and-place operation, semiconductor dice 102 are positioned with their active faces facing a carrier substrate 104, and held in position by an adhesive tape 106. Through-wafer connector elements 108 are also positioned on the carrier substrate. A first molding compound layer 110 is deposited over the dice 102 and through-wafer connector elements 108, and cured by heat and compression to form the reconstituted wafer 100.

The through-wafer connector elements 108 can be in any number of different configurations. For example, they can be in the form of a conductive metal bar, or a nonconductive structure with a conductive core. Furthermore, multiple connector elements can be provided in the form of a block of nonconductive material in which a plurality of conductive cores are encapsulated. By providing the connector elements in this form, distribution and spacing of the elements can be established in advance, and the pick-and-place operation in which they are positioned on the carrier can be significantly simplified.

Following formation of the molding compound layer 110, the reconstituted wafer 100 is debonded from the carrier substrate 104 and coupled to a temporary bonded carrier 115 via adhesive 117, as shown in FIG. 3. The back side of the reconstituted wafer 100 is then planarized to a selected thickness, as indicated schematically at P, producing a new back face 114 of the reconstituted wafer. The selected thickness is no greater than the length of the through-wafer connector elements 108 so that back contact surfaces 116 of the through-wafer connector elements are exposed at the back face 114 of the reconstituted wafer 100, thereby forming through-wafer vias 112. In this process, the dice 102 can be thinned to a selected thickness. For example, the parent semiconductor wafer from which the dice 102 are cut will typically have a thickness of 350 μm-750 μm. During the planarizing process of the reconstituted wafer 100, the dice may be thinned to as little as 100 μm, 50 μm, or even less.

Devices that are formed on semiconductor material substrates are generally formed on only one surface thereof, and occupy a relatively small part of the total thickness of the substrate. This surface is generally referred to as the active side, or front face. Therefore, for the purposes of the present disclosure and claims, the terms front and back are used to establish an orientation with reference to the active face of a semiconductor wafer or die. For example, reference to a front surface of some element of an assembly that includes a semiconductor die refers to the surface of that element that would be uppermost if the device as a whole were oriented so that the active face of the die was the uppermost part of the die. Of course, a back surface of an element is the surface that would be lowermost, given the same orientation of the device. Use of either term to refer to an element of such a device is not to be construed as indicating an actual physical orientation of the element, the device, or the associated semiconductor die, and, where used in a claim, does not limit the claim except as explained above.

The term planarize is used to refer to any process employed to produce a smooth, flat surface, and/or to thin a structure, including chemical and mechanical machining and grinding processes, polishing processes, etc.

According to one preferred embodiment, as shown in FIGS. 1-3, through-wafer vias 112 are formed by positioning through-wafer connector elements 108 on the carrier substrate 104 prior to formation of the molding compound layer 110. However, through-wafer vias 112 can be formed using any of a number of processes. In many processes, for example, the molding compound layer is formed, then apertures are drilled through the molding compound layer after which the apertures are filled with a conductive material. Methods for drilling apertures include etching, laser drilling, mechanical drilling, etc. Processes for filling apertures with conductive material include electroplating, electroless plating, solder paste deposition, conductive resin deposition, etc. Any appropriate process for making the through-wafer vias 112 can be employed, including those mentioned above.

Furthermore, as used in the claims, the term through-wafer via is to be read broadly as reading also on through-silicon vias formed in a semiconductor die embedded in the molding compound layer of a reconstituted wafer.

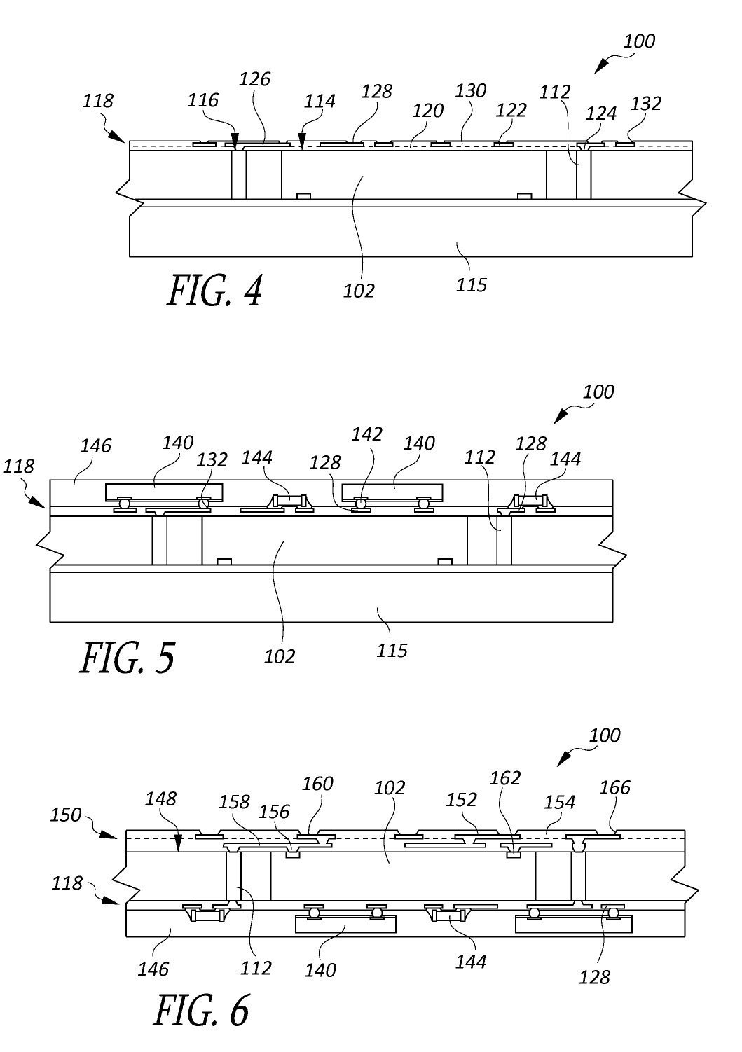

FIGS. 4-8 show an enlarged view of a smaller portion of the reconstituted wafer 100, defined in FIG. 3 by arrows 4-4, corresponding to a single package. Following the planarizing process described with reference to

FIG. 3, a back redistribution layer 118 is formed on the back face 114 of the reconstituted wafer 100. The back redistribution layer 118 is made according to known processes. In the embodiment shown in FIG. 4, the back redistribution layer 118 includes a first dielectric layer 120 in which openings are defined over the back contact surfaces 116 of the through-wafer vias 112. A layer of conductive material 122 such as, e.g., copper, is deposited and patterned to form vias 124, electrical traces 126, and contact pads 128. The vias 122 extend through the openings in the first dielectric layer 120 to make electrical contact with the back contact surfaces 116 of the through-wafer vias 112. A second dielectric layer 130 is formed over the first dielectric layer 120, with openings 132 defined over the contact pads 128 of the layer of conductive material 122. Though not shown in detail, the back redistribution layer 118 can also include, for example, an under-bump metallic layer over the contact pads 128.

As is known in the art, the dielectric material of a redistribution layer is typically formulated to act as a passivation barrier to protect underlying structures such as semiconductor surfaces, metallic layers, etc., and also to provide some degree of mechanical protection. Elements and details of the back redistribution layer 118 are shown as examples only. In practice, the back redistribution layer 118 may have any number of dielectric, passivation, and conductive layers, as necessary for the particular design. Determining factors may include the complexity of the circuit, the particular materials used, and the processes employed.

Turning now to FIG. 5, a plurality of secondary semiconductor dice 140 are positioned over the back redistribution layer 118 in contact with respective pluralities of the contact pads 128 through the openings 132. In the embodiment shown, the secondary dice 140 are configured as flip-chips, with solder balls 142 placing circuit contacts of the dice 140 in electrical contact with respective ones of the contact pads 128. Passive devices 144 are also shown positioned on the back redistribution layer 118 in electrical contact with respective contact pads 128 of the back redistribution layer. Passive devices are devices such as resistors, capacitors, and inductors that are commonly used in electronic circuits.

To couple the secondary dice 140 and passive devices 144 to the wafer 100, according to an embodiment, solder paste is first deposited over selected ones of the contact pads 128. In a pick-and-place operation, the passive devices 144 are placed on the back redistribution layer 118 over the selected ones of the contact pads 128, in contact with the solder paste. The flip-chip dice 140 are then positioned over others of the contact pads 128. A reflow procedure is then performed, in which the solder balls 142 and the solder paste reflow to mechanically and electrically couple the secondary dice 140 and passive devices 144 to the contact pads 128.

Following the reflow procedure, a molding compound layer 146 is deposited over the back redistribution layer 118, completely encapsulating the secondary dice 140 and the passive devices 144. According to an embodiment, the molding compound layer 146 is formulated as a molded underfill material, so that when it is deposited on the back face of the reconstituted wafer 100, it is drawn by capillary action under the flip chips 140 and the passive devices 144 to support and protect the solder joints. Once cured, the molded underfill material is in most respects indistinguishable from more convention molding compound material.

According to another embodiment, a layer of underfill material is first deposited under and around the flip chips 140 and passive devices 144, then a layer of more convention molding compound is deposited over the back redistribution layer 118 to encapsulate the secondary components. According to an embodiment, the underfill layer may be partially or fully cured prior to deposition of the molding compound.

Primary differences between underfill material and more conventional molding compound include viscosity and the size of the grains and/or fibers used as filler. In the case of the underfill material, the filler may comprise fibers in the 3-10 μm size, where typical molding compound may employ fibers in the range of 50-100 μm.

The flip-chip dice 140 and the passive devices 144 are shown as examples of devices that can be employed, according to some embodiments. In practice, the devices used will depend on the required functionality of the completed package, and may include semiconductor packages of various types and sizes, passive devices, and discrete active devices.

As shown in FIG. 6, the reconstituted wafer 100 is then separated from the temporary bonded carrier 115 and turned over to expose a front face 148 of the reconstituted wafer. A front redistribution layer 150 is formed over the front face. In the embodiment shown, the front redistribution layer 150 includes first and second layers of conductive material 152 such as, e.g., copper, separated by corresponding layers of dielectric material, including an outer layer 154. The conductive material forms vias 156, electrical traces 158, and contact pads 160. The vias 156 make electrical contact with circuit contacts 162 of the semiconductor dice 102 and front contact surfaces 164 of the through-wafer vias 112. The electrical traces 158 interconnect selected combinations of the circuit contacts 162, the plurality of through-wafer vias 112, and the contact pads 160. The outer layer 154 of dielectric material includes openings 166 positioned over the contact pads 160.

As with the back redistribution layer 118, details of the front redistribution layer 150 that are shown are merely exemplary. For example, the front redistribution layer 150 is shown having two layers of conductive material, such as might be provided for a more complicated wiring pattern. The configuration used in practice will again depend on the specific device.

In the case of the embodiment shown, both the back and front redistribution layers 118, 150 can be defined as fan-out redistribution layers, inasmuch as they include contact pads positioned outside the boundaries of the semiconductor dice 102.

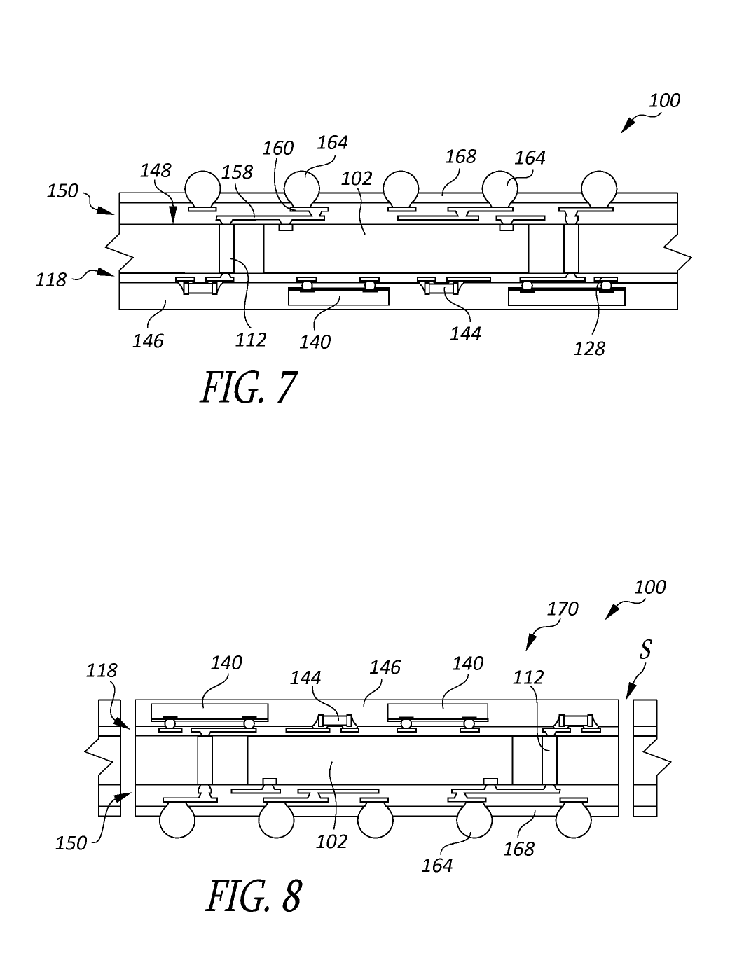

Turning to FIG. 7, following formation of the front redistribution layer 150, solder balls 164 are positioned over the contact pads 160 of the front redistribution layer 150 then reflowed to bring the solder balls 164 into full contact with the contact pads. The solder balls 164 can be positioned using any of a number of different methods, including various ball drop processes, as well as, for example, deposition of solder paste followed by a reflow procedure.

A front molding compound layer 168 is deposited over the front redistribution layer 150. The front molding compound layer 168 is formulated to flow around the solder balls 164, and has a thickness that is less than a height of the solder balls from the front face of the front redistribution layer 150. Thus, on each of the finished packages, a portion of each solder ball will extend from the front molding compound layer 168 so that the package can be coupled to contact pads of a circuit board in a reflow process. Meanwhile, the front molding compound layer 168 will maintain a selected spacing between the finished package and the circuit board, and will provide lateral support to the portions of the solder balls 164 that remain encapsulated by the front molding compound layer, reducing the incidence of solder joint failure caused by thermal mismatch.

Finally, as shown in FIG. 8 at S, the reconstituted wafer 100 is singulated to produce a plurality of individual packages 170, each having a respective one of the mother dice 102, portions of the back and front redistribution layers 118, 150 and the back and front molding compound layers 146, 168, and respective pluralities of secondary dice 140, passive devices 142, and solder balls 164.

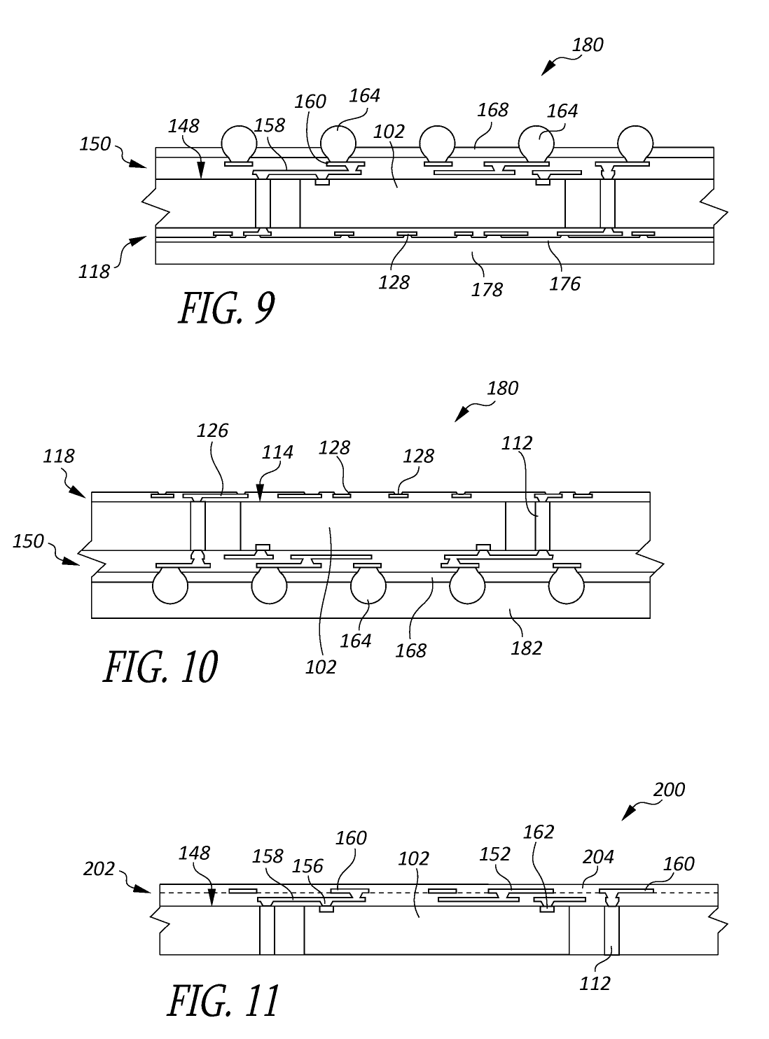

According to an alternative embodiment, as shown in FIG. 9, following the formation of the back redistribution layer 118 described with reference to FIG. 4, a temporary bonded carrier 178 is coupled to reconstituted wafer 180 over the back redistribution layer 118. The reconstituted wafer 180 is then turned over for processing on the front face 148 of the reconstituted wafer.

The front redistribution layer 150, formed substantially as described with reference to FIG. 6, and the solder balls 164 and front molding compound layer 168 are positioned over the front redistribution layer 150, substantially as described with reference the reconstituted wafer 100 of FIG. 7.

Following the curing of the front molding compound layer 168, a temporary protective layer 182 is formed over the front redistribution layer 150, encapsulating the solder balls 164, as shown in FIG. 10. The reconstituted wafer 180 is then again turned over and the temporary bonded carrier 178 is removed to expose the back redistribution layer 118 of the reconstituted wafer 180. The process then proceeds as described with reference to FIG. 5, in which secondary components are coupled to the back redistribution layer, and the back molding compound layer 146 is deposited and cured. The temporary protective layer 182 is then removed, and the reconstituted wafer 180 is singulated, substantially as described with reference to the reconstituted wafer 100 of FIG. 8.

According to a further alternative embodiment, when the first molding compound layer 110 is formed, as described with reference to FIG. 2, a thickness of the first molding compound layer is selected to be sufficient to provide adequate support to the reconstituted wafer 180 during subsequent process steps. The planarizing process described with reference to FIG. 3 is postponed, and the temporary bonded carrier 178 is omitted. The remainder of the processes described with reference to FIG. 9 are performed as disclosed, and the temporary protective layer 182 is formed over the front face as described with reference to FIG. 10. The reconstituted wafer 180 is then turned over, and the planarizing process is performed, defining the front face 114 of the reconstituted wafer 180, as described with reference to the reconstituted wafer 100 of FIG. 3. The remainder of the processes described with reference to FIGS. 4 and 5 are performed, after which the temporary protective layer 182 is removed, and the reconstituted wafer 180 is singulated.

FIGS. 11-14 show a reconstituted wafer 200 at respective stages of a manufacturing process according to another embodiment. As shown in FIG. 11, following the process steps described through FIG. 3, the reconstituted wafer 200 is turned over and a front redistribution layer 202 is formed on the front face 148 of the wafer 200. Formation of the front redistribution layer 202 proceeds substantially as described with reference to FIG. 6, except that the outer layer 204 of dielectric material completely covers the surface of the front redistribution layer, in contrast to previously described embodiments, in which the outer layer includes openings over contact pads 160.

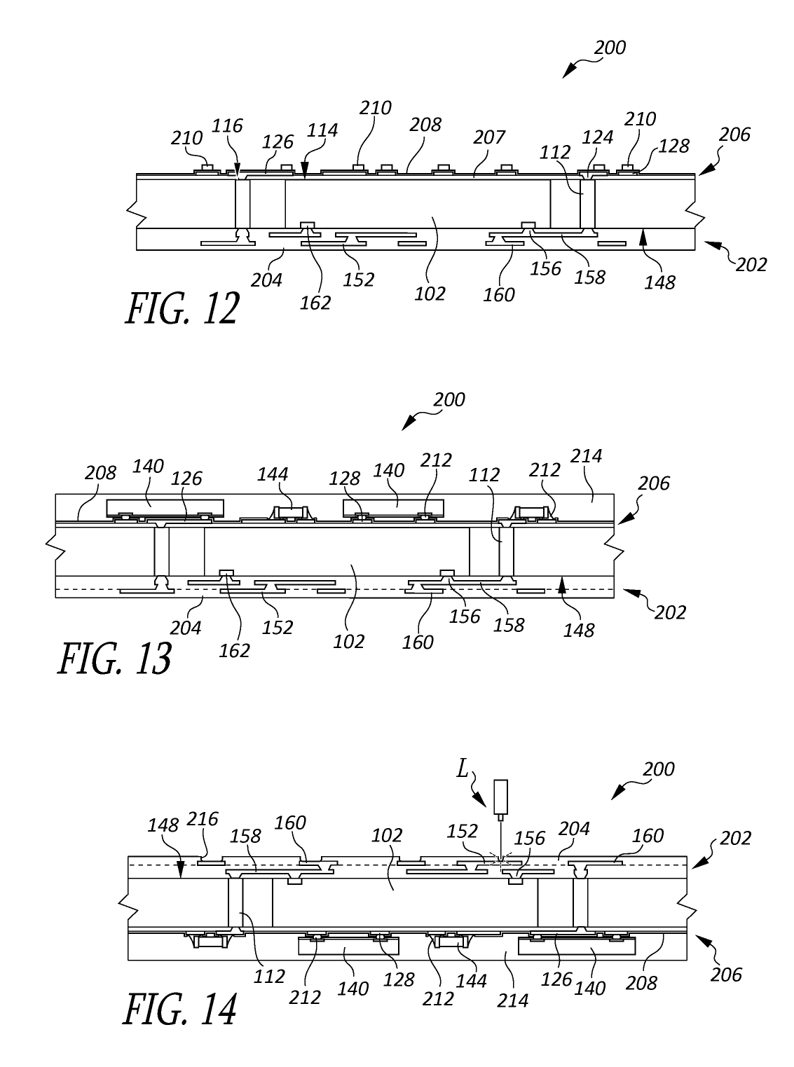

Following formation of the front redistribution layer 202, the reconstituted wafer 200 is turned over, as shown in FIG. 12, and a back redistribution layer 206 is formed on the back face 114 of the wafer 200. In the example shown, a first dielectric layer 207 is positioned on the back face 114, patterned to define openings over back contact surfaces 116 of the TSVs 112. A conductive layer is then deposited and patterned to form vias 124, electrical traces 126, and contact pads 128. In the embodiment of FIG. 12, no final dielectric layer is deposited over the conductive layer. Instead, a chemical coating 208 is deposited over the back surface of the wafer 200. The material of the chemical coating is formulated to dissolve in activated solder flux, i.e., solder flux that is at a temperature at which it operates to clean and deoxidize materials to facilitate a satisfactory solder joint. Solder paste 210 is deposited on the chemical coating 208 in positions corresponding to the contact pads 128.

Turning to FIG. 13, the secondary components 140, 144 are positioned on the back face of the wafer in contact with the solder paste 210. A reflow process is performed, in which the solder paste liquefies and forms solder connections 212 between contacts of the secondary components 140, 144 and the contact pads 128 of the back redistribution layer 206. As flux in the solder paste 210 is heated, it acts to dissolve the chemical coating 208 over the contact pads 128, preferably at a temperature that is slightly lower than the liquidus temperature of solder in the paste, so that the solder is in contact with the contact pads 128 as it reflows. Following the reflow step, a molding compound layer 214 is formed over the secondary components substantially as described above with reference to the molding compound layer 146 of FIG. 5.

Following formation of the molding compound layer 214, the wafer 200 is again turned over, as shown in FIG. 14. Openings 216 are made in the dielectric layer 204 by laser ablation, as shown at L, to receive solder balls. Following the formation of the openings 216, the remaining processes are performed substantially as described above with reference to FIGS. 6-8.

The material of the chemical coating 208 described with reference to FIGS. 12 and 13 differs in several respects from material that would typically be used as the outermost dielectric layer of a redistribution layer. As a rule, according to known processes, the dielectric material of a redistribution layer is formulated and processed to be relatively resistant to chemicals that may be used in later process steps, and also to provide a degree of protection from abrasion that might occur over the life of the device. Polyimides are commonly used as dielectrics in redistribution layers because of their toughness and chemical properties. To form a polyimide dielectric layer, the material is first deposited by, e.g., spin coating, then partially cured in an oven. A photoresist layer is then deposited and patterned to provide openings over selected portions of the polyimide layer. The selected portions are then exposed to a developing solution that chemically alters the polyimide material, which prevents further curing, after which a second bake is performed to fully cure the unexposed portions of the layer. Finally, the surface is washed to remove the photoresist layer and the uncured selected portions of the polyimide layer. The resulting layer is electrically nonconductive, substantially chemically inert, and very tough.

At locations where openings are provided in the dielectric layer over contact pads, under-bump metallization layers are often provided, in part, to prevent oxidation of the contact pad material exposed by the openings in the dielectric layer.

In contrast to the process described above, the material of the chemical coating 208 can be deposited by various processes, including spraying, dipping, or screen printing, then air drying the wafer 200. The chemical coating 208 serves primarily to prevent oxidation of the contact pad material, and is preferably electrically nonconductive. There is no particular requirement of durability or chemical resistance because the back molding compound layer 214 that will be deposited over the secondary elements provides the physical and chemical protection. In fact, as previously noted, the material of the chemical coating is specifically formulated to dissolve under selected circumstances. According to a preferred embodiment, the chemical coating is formulated to be easily dissolved by solder fluxes that are commonly used in semiconductor packaging processes.

In the embodiment of FIGS. 11-14, secondary semiconductor dice 140 are placed in direct contact with the solder paste 210, and are therefore not previously provided with solderballs. In embodiments where the secondary dice 140 are in flip-chip configuration with preattached solderballs, a layer of flux can be deposited over the entire back surface of the wafer 200 so that during reflow, the chemical coating 208 is entirely dissolved. Furthermore, while the chemical coating 208 is shown as being a continuous coating over the entire back surface, according to other embodiments, the chemical coating 208 is deposited only over the contact pads 128.

With regard to the various orders of operation described above, there are, of course, benefits to performing all process steps related to one side of a reconstituted wafer prior to turning the wafer, as described, for example, with reference to the embodiment of FIGS. 1-8. However, depending on materials chosen for the redistribution layers and molding compound layers, thermal mismatch, i.e., differences in rates of thermal expansion, can cause the reconstituted wafer 100 to lose planarity if all of the processes relating to one side of the reconstituted wafer are performed prior to those related to the other side. By turning the reconstituted wafer partway through the manufacturing process, elements on the front and back of the wafer are formed in a more symmetrical manner, resulting in a greater resistance to loss of planarity. Other reasons for selecting a specific order of operation may include, for example, availability, durability, and cost of material, compatibility of processes, scheduling of processing equipment, etc.

Typically, as described with reference to the embodiment of FIGS. 1-8, formation of a reconstituted wafer is performed on a metal carrier substrate having dimensions that are larger than those of the reconstituted wafer. Following deposition and curing of the molding compound layer, the reconstituted wafer is then transferred to a temporary bonded carrier having dimensions that correspond to those of the reconstituted wafer. The new carrier substrate may not be metal, but may be a resin material, or glass, or silicon, etc. Switching to a different substrate can be done to avoid problems of thermal mismatch, to facilitate handling by automatic machinery, etc. However, for the purposes of the claims, unless specifically defined otherwise, carrier substrate is to be construed generically, as reading on any substrate or carrier, or succession of such, to which a wafer is bonded during processing, but that is not part of the final package.

The semiconductor packages described above provide several advantages over other types of packages used for similar systems. Some of the advantages and benefits are described below. By providing the necessary secondary active and passive components in a same package, those components are removed from the circuit board on which the package is to be mounted, and will normally occupy less space than the package and secondary components would otherwise collectively occupy. Additionally, the wiring circuit of the circuit board is simplified because it is not necessary to provide interconnecting lines between the mother chip and the secondary components.

Encapsulating all of the associated components together in the package protects all of the components and the interconnecting circuits.

In typical package-on-package systems, the upper package(s) is usually about the same size, in lateral dimensions, as the lower package. In such cases it would be possible to attach the upper packages at the wafer stage, then turn the wafer over to attach solder balls. However, in cases where multiple upper packages or components of different sizes and heights are positioned on a lower package, it is no longer safe to turn the wafer over for further processing, because pressure applied to the wafer during application of flux, solder balls, etc. can damage the devices on the opposite side, or can break the wafer. On the other hand, attaching the solder balls first is problematic because the reflow temperature of the solderballs should be lower than the temperature used to reflow the upper solder joints so that the PoP package can be later attached to a circuit board without desoldering the upper packages. Thus, wafer level processing of more complex PoP packages is discouraged.

According to some embodiments, the first problem is obviated by formation of the back molding compound layer, which provides a smooth, even surface on the back side of the wafer so that the wafer can be safely turned over for work on the front side of the wafer. In embodiments in which the front side of the wafer is completed prior to positioning the secondary components, a temporary protective layer formed over the solder balls, such as layer 182 described with reference to the embodiment of FIGS. 9 and 10, prevents the solder balls from being damaged by the reflow process by which the secondary components are attached, The solder of the solder balls will liquefy during the reflow, but will be held in position, and will reharden in the same form when the material cools.

A particular benefit is provided in reduced manufacturing costs. Known packages having similar functionality are typically manufactured on a per-unit basis, in which the mother chip is encapsulated in a primary package with contact pads on an upper surface, and additional components or packages are assembled onto the primary package. In contrast, the packages of the disclosed embodiments are fully assembled at the wafer level, so that the last step in the process is singulation of the wafer. Thus, all of the process steps are performed on all of the individual devices substantially simultaneously, which results in a significant reduction of cost, as compared to the known processes.

Additional cost reductions are made possible by aspects of the embodiment described with reference to FIGS. 11-14. By forming a continuous dielectric layer over the underlying metallic elements, it is not necessary to attach a temporary bonded carrier before turning the wafer, as described with reference to the embodiment of FIGS. 9 and 10. Additionally, omitting the patterning step that would otherwise be necessary in order to form openings over contact pads on the front of the wafer offsets some or all of the expense associated with the laser ablation by which the openings are later formed.

Finally, deposition of the chemical coating, as described with reference to the embodiment of FIGS. 11-14, eliminates the much more costly and time consuming steps of forming the final dielectric layer of the back redistribution layer.

A number of processes are referred to or described above as examples of respective known or previously disclosed processes. These include, for example, the formation and/or positioning of through-wafer vias, redistribution layers, molding compound layers, and solder balls. The following U.S. patent applications include descriptions of these and other related processes: Ser. No. 12/651,304, filed Dec. 31, 2009; Ser. No. 12/651,365, filed Dec. 31, 2009; Ser. No. 12/651,362, filed Dec. 31, 2009; Ser. No. 12/651,295, filed Dec. 31, 2009; Ser. No. 12/977,697, filed Dec. 23, 2010; Ser. No. 13/173,991, filed Jun. 30, 2011; Ser. No. 13/232,780, filed Sep. 14, 2011; Ser. No. 13/312,562, filed Dec. 6, 2011; Ser. No. 13/340,575, filed Dec. 29, 2011; and Ser. No. 13/485,624, filed May 31, 2012. These applications are incorporated herein in their entireties.

The unit symbol “μm” is used herein to refer to a value in microns. One micron is equal to 1×10⁻⁶ meters.

For the purposes of the present disclosure and claims, redistribution layer is a structure that includes one or more layers of dielectrics and conductors that are formed or deposited on an underlying substrate or layer to create and isolate redistributing signal paths of a semiconductor die.

Terms such as circuit pad, contact pad, contact surface, etc., are used substantially synonymously to refer to different structures that are functionally, and often structurally, similar. Accordingly, where the claims use such terms, the language is for clarity purposes to differentiate one element from another and not because they necessarily have different structures, and the corresponding elements are not limited by the terms as used in the description.

Molding compounds are substances used to encapsulate semiconductor devices in many different packaging processes, are typically composite materials made from blends of ingredients such as, e.g., resins, hardeners, silicas, catalysts, pigments, and release agents, and are generally provided in a substantially liquid form of a selected viscosity so that they can be injected or poured. Molding compounds are available in a very wide range of formulations from different manufacturers and to meet many different criteria. Accordingly, the term molding compound is to be construed broadly to apply to all such compounds.

Ordinal numbers, e.g., first, second, third, etc., are used in the claims according to conventional claim practice, i.e., for the purpose of clearly distinguishing between claimed elements or features thereof. The use of such numbers does not suggest any other relationship, e.g., order of operation or relative position of such elements. Furthermore, ordinal numbers used in the claims have no specific correspondence to those used in the specification to refer to elements of disclosed embodiments on which those claims read, nor to numbers used in unrelated claims to designate similar elements or features.

The term over is used in the specification and claims to refer to the relative positions of two or more elements with respect to a third element, although the third element may be implied by the context. The term should not be construed as requiring direct physical contact between the elements, nor should it be construed as indicating any particular orientation, either absolute, or with respect to the third element. So, for example, if a claim recites a second layer positioned over a first layer on a substrate, this phrase indicates that the second layer is coupled to the substrate and that the first layer is between the second layer and the substrate. It does not indicate that the layers are necessarily in direct physical contact with each other or with the substrate, but may instead have one or more intervening layers or structures. It also does not indicate that the substrate is oriented in a manner that places the second layer physically above the first layer, nor that, for example, the layers are positioned over a front face of the substrate, as that term is used herein.

The abstract of the present disclosure is provided as a brief outline of some of the principles of the invention according to one embodiment, and is not intended as a complete or definitive description of any embodiment thereof, nor should it be relied upon to define terms used in the specification or claims. The abstract does not limit the scope of the claims.

The various embodiments described above can be combined to provide further embodiments. For example, a selected feature of one embodiment can be combined with a feature of another embodiment to provide a new embodiment. Furthermore, unless explicitly set forth in the claims, no element or feature is essential to any particular embodiment. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled.

Accordingly, the claims are not limited by the disclosure.

1. A process for manufacturing a semiconductor package, comprising:
forming a first redistribution layer on a front face of a reconstituted wafer that includes a plurality of semiconductor dice embedded in a first layer of molding compound, and a plurality of through-wafer vias, each of the plurality of semiconductor dice having a respective plurality of circuit contacts, the first redistribution layer having a first plurality of contact pads and a first plurality of electrically conductive traces interconnecting selected combinations of ones of the circuit contacts, ones of the plurality of through-wafer vias, and ones of the first plurality of contact pads;
forming a second redistribution layer on a back face of the reconstituted wafer, the second redistribution layer having a second plurality of contact pads and a second plurality of electrically conductive traces interconnecting selected combinations of ones of the plurality of through-wafer vias and ones of the second plurality of contact pads;
positioning a plurality of secondary components on the back face of the reconstituted wafer and electrically coupling each to a respective group of the second plurality of contact pads;
depositing and curing a second layer of molding compound on the back face of the reconstituted wafer, encapsulating the plurality of secondary components; and
singulating the reconstituted wafer into individual packages so that each of the individual packages includes a respective portion of each of the first and second layers of molding compound, a portion of each of the first and second fan-out redistribution layers, a portion of the plurality of through-wafer vias, at least one of the plurality of semiconductor dice, and at least one of the plurality of secondary components.

2. The process of claim 1 wherein the positioning the plurality of secondary components comprises positioning a plurality of secondary semiconductor dice.

3. The process of claim 2 wherein the positioning the plurality of secondary components comprises positioning a plurality of passive components, and wherein each of the individual packages includes at least one of each of the plurality of secondary semiconductor dice and the plurality of passive components.

4. The process of claim 1, comprising:
positioning a plurality of solder balls over the front face of the reconstituted wafer, each in electrical contact with a respective one of the first plurality of contact pads; and
depositing and curing a third layer of molding compound over the front face of the reconstituted wafer, the third layer of molding compound having a thickness that is less than a height of each of the plurality of solders balls above a front face of the first redistribution layer.

5. The process of claim 4 wherein the depositing the third layer of molding compound comprises depositing the third layer of molding compound after the positioning the plurality of solder balls, and allowing the third layer of molding compound to contact and flow around each of the plurality of solder balls.

6. The process of claim 4 wherein the positioning the plurality of solder balls and the depositing the third layer of molding compound are performed prior to the singulating.

7. The process of claim 1 wherein the depositing and curing a second layer of molding compound over the back face of the reconstituted wafer comprises depositing and curing a layer of underfill material, thereby wholly encapsulating the plurality of secondary components in the layer of underfill material.

8. The process of claim 1 wherein the depositing and curing a second layer of molding compound over the back face of the reconstituted wafer comprises:
depositing and curing underfill material on the back face of the reconstituted wafer so that the underfill material flows between each of the plurality of secondary components and the back face of the second redistribution layer; and
depositing and curing molding compound material over the back face of the reconstituted wafer, wholly encapsulating the plurality of secondary components and the cured underfill material in the molding compound material.

9. The process of claim 1 wherein the positioning the plurality of secondary components comprises: depositing solder paste over the corresponding groups of contact pads; positioning each of the plurality of secondary components in contact with the solder paste positioned over the respective contact pads; and reflowing the solder paste.

10. The process of claim 1 comprising, prior to positioning the secondary components, or depositing and curing the second molding compound layer:
positioning a plurality of solder balls over the front face of the reconstituted wafer, each in electrical contact with a respective one of the first plurality of contact pads;
depositing and curing a third layer of molding compound over the front face of the reconstituted wafer, partially encapsulating the plurality of solder balls; and
depositing a temporary protective layer over the solder balls and third layer of molding compound.

11. The process of claim 10 comprising, prior to positioning the plurality of solder balls, positioning a temporary protective layer over the second redistribution layer.

12. The process of claim 1, comprising forming the reconstituted wafer, including:
positioning the plurality of semiconductor dice on a carrier substrate;
positioning a plurality of through-wafer connector elements on the carrier substrate;
depositing the first layer of molding compound on the carrier substrate over the plurality of semiconductor dice and the plurality of through-wafer connector elements;
curing the layer of molding compound;
planarizing the first layer of molding compound to a thickness that is no greater that a length of one of the plurality of through-wafer connector elements.

13. The process of claim 1 wherein the forming a first redistribution layer comprises:
depositing a layer of dielectric material over the first plurality of contact pads; and
forming an opening in the layer of dielectric material over each of the first plurality of contact pads by laser ablation.

14. The process of claim 1 wherein forming the second redistribution layer comprises:
forming the second plurality of contact pads; and
depositing a chemical coating over the second plurality of contact pads,
and wherein the positioning a plurality of secondary components comprises:
depositing solder paste over each of the second plurality of contact pads and the chemical coating;
positioning each of the secondary components in contact with the solder paste over a respective group of the second plurality of contact pads; and
coupling each of the secondary components to the respective group of the second plurality of contact pads by reflowing the solder paste and dissolving portions of the chemical coating under the solder paste.

15. A process, comprising:
positioning, on a back face of a reconstituted wafer that includes a plurality of semiconductor dice embedded in a first molding compound layer, a plurality of secondary semiconductor dice and a plurality of passive components, each of the plurality of secondary semiconductor dice and each of the plurality of passive components being in electrical contact with a respective group of a plurality of contact pads of a first redistribution layer formed on the back face of the reconstituted wafer;
depositing and curing a second molding compound layer on the back face of the molding compound layer; and
singulating the reconstituted wafer, including singulating the first and second molding compound layers, into individual packages.

16. The process of claim 15, comprising, prior to the singulating:
positioning a plurality of solder balls over a front face of the reconstituted wafer, each in electrical contact with a respective one of a plurality of contact pads of a second redistribution layer formed on the front face of the reconstituted wafer; and
depositing, after positioning the plurality of solder balls, a third molding compound layer over the front face of the reconstituted wafer, including controlling a thickness of the third molding compound layer to be less than a height of the plurality of solder balls above the second redistribution layer.

17. The process of claim 16, comprising, prior to the positioning the secondary semiconductor dice and passive components:
attaching a temporary bonded carrier over the back face of the reconstituted wafer;
positioning the solder balls over the front face of the reconstituted wafer and depositing the third molding compound layer;
depositing a temporary protective layer over the front face of the reconstituted wafer, wholly encapsulating the plurality of solder balls; and
after depositing the temporary protective layer over the front face of the reconstituted wafer, removing the temporary bonded carrier from over the back face of the reconstituted wafer.

18. The process of claim 15, comprising forming the first redistribution layer on the back face of the reconstituted wafer, including depositing a chemical coating over the plurality of contact pads of the first redistribution layer, and wherein the positioning the secondary semiconductor dice and passive components includes:
depositing solder paste over the chemical coating;
positioning the secondary semiconductor dice and passive components over the respective group of contact pads; and
reflowing the solder paste; and dissolving the chemical coating lying between the solder paste and the plurality of contact pads.

19. A process, comprising:
forming, on a first face of a reconstituted wafer that includes a plurality of semiconductor dice embedded in a first molding compound layer, a first redistribution layer, including:
forming a dielectric layer on the first face of the reconstituted wafer,
forming a plurality of contact pads on the dielectric layer, and
forming, on the contact pads, a chemical coating that is susceptible to dissolution by solder flux;
depositing solder flux on the chemical coating;
positioning electrical contact surfaces of a component on respective ones of the contact pads;
dissolving a portion of the chemical coating in the solder flux by heating the solder flux;
forming a solder joint between each of the electrical contact surfaces and the respective one of the contact pads;
forming a second molding compound layer on the first face of the reconstituted wafer over the first redistribution layer, encapsulating the component.

20. The process of claim 19 wherein the depositing solder flux comprises depositing solder paste that includes solder flux.

21. The process of claim 19, comprising forming, on a second face of the reconstituted wafer, a second redistribution layer, including:
forming a first dielectric layer on the second face of the reconstituted wafer,
forming a plurality of contact pads on the first dielectric layer, and
forming a second dielectric layer on the first dielectric layer completely covering the plurality of contact pads.

22. The process of claim 21 comprising forming openings in the second dielectric layer over each of the plurality of contact pads by laser ablation.
